(19) United States
(12) Patent Application Publication
(10) Pub. No.: US 2020/0168482 A1
(43) Pub. Date: May 28, 2020

(54) SUBSTRATE PROCESSING APPARATUS AND SUBSTRATE PROCESSING METHOD

(71) Applicant: Tokyo Electron Limited, Tokyo (JP)

(72) Inventors: Hiroaki Inadomi, Koshi City (JP); Satoshi Biwa, Koshi City (JP); Satoshi Okamura, Koshi City (JP)

(21) Appl. No.: 16/690,340

(22) Filed: Nov. 21, 2019

(30) Foreign Application Priority Data
Nov. 22, 2018 (JP) 2018-218900

(51) Int. Cl. H01L 21/67; H01L 21/02

(52) U.S. Cl. CPC H01L 21/67034; H01L 21/02101

(57) ABSTRACT

A substrate processing apparatus configured to perform a drying processing of drying substrates by using a processing fluid in a supercritical state includes a processing vessel and multiple holders. In the processing vessel, the drying processing is performed. The multiple holders are respectively configured to hold the substrates within the processing vessel.

### CROSS-REFERENCE TO RELATED APPLICATION

This application claims the benefit of Japanese Patent Application No. 2018-218900 filed on Nov. 22, 2018, the entire disclosures of which are incorporated herein by reference.

### TECHNICAL FIELD

The various aspects and embodiments described herein pertain generally to a substrate processing apparatus and a substrate processing method.

### BACKGROUND

Conventionally, as a technique of removing moisture remaining on a surface of a substrate while suppressing a pattern collapse, there is known a supercritical drying technique of drying the substrate by using a supercritical fluid which is obtained under a high pressure.

Patent Document 1: Japanese Patent Laid-open Publication No. 2011-009299

### SUMMARY

In one exemplary embodiment, a substrate processing apparatus configured to perform a drying processing of drying substrates by using a processing fluid in a supercritical state includes a processing vessel and multiple holders. In the processing vessel, the drying processing is performed. The multiple holders are respectively configured to hold the substrates within the processing vessel.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic cross sectional view of a substrate processing system according to a first exemplary embodiment, seen from above;

FIG. 2 is a flowchart illustrating a sequence of a series of substrate processings performed in the substrate processing system according to the first exemplary embodiment;

FIG. 3 is a diagram illustrating a configuration example of a liquid processing unit;

FIG. 4 is a schematic cross sectional view illustrating a configuration of a drying unit according to the first exemplary embodiment;

FIG. 5 is a schematic cross sectional view illustrating an example of a state in which a plurality of wafers is accommodated in a processing vessel;

FIG. 6 is a schematic cross sectional view illustrating an example of a flow path for a processing fluid in a processing space;

FIG. 7 is a schematic cross sectional view illustrating a configuration of a drying unit according to a second exemplary embodiment;

FIG. 8 is a schematic cross sectional view illustrating a configuration of a drying unit according to a third exemplary embodiment;

FIG. 9 is a schematic cross sectional view illustrating a configuration of a drying unit according to a fourth exemplary embodiment;

FIG. 10 is a schematic cross sectional view illustrating a configuration of a drying unit according to a fifth exemplary embodiment;

FIG. 11 is a schematic cross sectional view illustrating a configuration of a drying unit according to a sixth exemplary embodiment;

FIG. 12 is a schematic plan view illustrating a configuration of a holder in the sixth exemplary embodiment; and

FIG. 13 is a schematic cross sectional view illustrating a configuration of a drying unit according to a seventh exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various embodiments (hereinafter, referred to as “exemplary embodiments”) for implementing a substrate processing apparatus and a substrate processing method according to the present disclosure will be described with reference to the accompanying drawings. However, it should be noted that the substrate processing apparatus and the substrate processing method according to the present disclosure are not limited to the exemplary embodiments. Further, the various exemplary embodiments can be appropriately combined as long as the contents of processings are not contradictory. Further, in the following exemplary embodiments, same parts will be assigned same reference numerals and redundant description will be omitted.

<First Exemplary Embodiment>

[1. Configuration of Substrate Processing System]

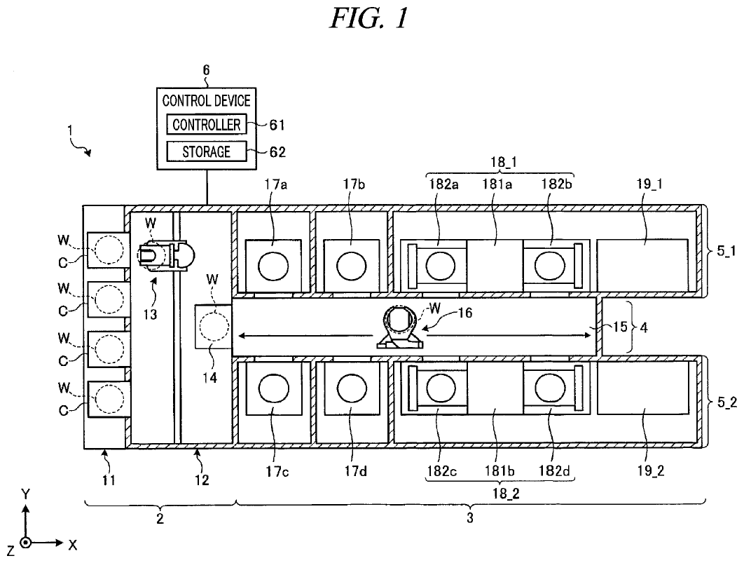

First, a configuration of a substrate processing system according to a first exemplary embodiment will be discussed with reference to FIG. 1. FIG. 1 is a schematic cross sectional view of the substrate processing system according to the first exemplary embodiment, seen from above. Further, in the following, in order to clarify positional relationships, the X-axis, the Y-axis and the Z-axis which are orthogonal to each other will be defined. The positive Z-axis direction will be regarded as a vertically upward direction.

As illustrated in FIG. 1, the substrate processing system 1 includes a carry-in/out station 2 and a processing station 3. The carry-in/out station 2 and the processing station 3 are provided adjacent to each other.

(Carry-In/Out Station 2)

The carry-in/out station 2 is provided with a carrier placing section 11 and a transfer section 12. A plurality of carriers C each accommodating a multiple number of semiconductor wafers W (hereinafter, referred to as “wafers W”) horizontally is placed in the carrier placing section 11.

The transfer section 12 is provided adjacent to the carrier placing section 11. A transfer device 13 and a delivery unit 14 are provided within the transfer section 12.

The transfer device 13 is equipped with a wafer holding mechanism configured to hold the wafer W. Further, the transfer device 13 is configured to be movable horizontally and vertically and pivotable around a vertical axis, and is configured to transfer the wafer W between the carrier C and the delivery unit 14 by using the wafer holding mechanism.

(Processing Station 3)

The processing station 3 is provided adjacent to the transfer section 12. The processing station 3 is equipped with a transfer block 4 and a plurality of (here, two) processing blocks 5_1 and 5_2.

(Transfer Block 4)

The transfer block 4 has a transfer area 15 and a transfer device 16. The transfer area 15 is, for example, a rectangular parallelepiped area extending in an arrangement direction (X-axis direction) of the carry-in/out station 2 and the processing station 3.

The transfer device 16 is disposed in the transfer area 15. The transfer device 16 is equipped with a wafer holding mechanism configured to hold the wafer W. Further, the transfer device 16 is movable horizontally and vertically and pivotable around a vertical axis, and is configured to transfer the wafer W between the delivery unit 14 and the processing blocks 5 by using the wafer holding mechanism.

The processing blocks 5_1 and 5_2 are disposed adjacent to the transfer area 15 at both sides of the transfer area 15. To elaborate, the processing block 5_1 is disposed at one side (positive Y-axis side) of the transfer area 15 in a direction (Y-axis direction) orthogonal to the arrangement direction (X-axis direction) of the carry-in/out station 2 and the processing station 3, and the processing block 5_2 is disposed at the other side (negative Y-axis side).

The processing block 5_1 is equipped with a plurality of (here, two) liquid processing units 17a and 17b, a drying unit 18_1 and a supply unit 19_1. Further, the processing block 5_2 is equipped with a plurality of (here, two) liquid processing units 17c and 17d, a drying unit 18_2 and a supply unit 19_2.

In the following description, when the processing blocks 5_1 and 5_2 need not be distinguished from each other, each of them will sometimes be referred to as “processing block 5.” Likewise, each of the liquid processing units 17a to 17d will sometimes be referred to as “liquid processing unit 17”; the drying units 18_1 and 18_2, “drying unit 18”; and the supply units 19_1 and 19_2, “supply unit 19.”

The liquid processing unit 17 is configured to perform a cleaning processing of cleaning a top surface, that is, a pattern formation surface of the wafer W. Further, the liquid processing unit 17 performs a liquid film forming processing of forming a liquid film on the top surface of the wafer W after being subjected to the cleaning processing. A configuration of the liquid processing unit 17 will be elaborated later.

The drying unit 18 is configured to perform a supercritical drying processing on the wafer W after being subjected to the liquid film forming processing. To be specific, the drying unit 18 is configured to dry the wafer W after being subjected to the liquid film forming processing by bringing this wafer W into contact with a processing fluid in a supercritical state. A configuration of the drying unit 18 will be described later.

The supply unit 19 is configured to supply the processing fluid into the drying unit 18. To elaborate, the supply unit 19 is equipped with a supply device group including a flowmeter, a flow rate controller, a back pressure valve, a heater, and so forth; and a housing accommodating therein the supply device group. In the first exemplary embodiment, the supply unit 19 supplies CO₂ as the processing fluid into the drying unit 18.

In each processing block 5, the liquid processing units 17, the drying unit 18 and the supply unit 19 are arranged along the transfer area 15 (that is, in the X-axis direction). Among the liquid processing unit 17, the drying unit 18 and the supply unit 19, the liquid processing unit 17 is placed at a position nearest to the carry-in/out station 2, and the supply unit 19 is placed at a position farthest from the carry-in/out station 2.

The drying unit 18_1 includes a processing area 181a in which the supercritical drying processing is performed; and a plurality of (here, two) delivery areas 182a and 182b in which the wafer W is delivered between the transfer block 4 and the processing area 181a. In the first exemplary embodiment, the processing area 181a and the delivery areas 182a and 182b are arranged along the transfer area 15. To elaborate, the delivery areas 182a and 182b are disposed at two opposite sides of the processing area 181a in the X-axis direction, that is, at a positive X-axis side and a negative X-axis side of the processing area 181a.

Likewise, the drying unit 18_2 includes a processing area 181b in which the supercritical drying processing is performed; and a plurality of (here, two) delivery areas 182c and 182d in which the wafer W is delivered between the transfer block 4 and the processing area 181b. In the first exemplary embodiment, the processing area 181b and the delivery areas 182c and 182d are arranged along the transfer area 15. To elaborate, the delivery areas 182c and 182d are disposed at two opposite sides of the processing area 181b in the X-axis direction, that is, at a positive X-axis side and a negative X-axis side of the processing area 181b.

Further, in the following description, when the drying units 18_1 and 18_2 need not be distinguished from each other, they will sometimes be referred to as “drying unit 18.” Likewise, the processing areas 181a and 181b will sometimes be referred to as “processing area 18,” and the delivery areas 182a to 182d will sometimes be referred to as “delivery area 182.”

(Control Device 6)

The substrate processing system 1 is equipped with a control device 6. The control device 6 may be, by way of example, a computer, and includes a controller 61 and a storage 62.

The controller 61 includes a microcomputer having a CPU (Central Processing Unit), a ROM (Read Only Memory), a RAM (Random Access Memory), an input/output port, and so forth; and various kinds of circuits. The CPU of the microcomputer controls the transfer devices 13 and 16, the liquid processing unit 17, the drying unit 18 and the supply unit 19 by reading out and executing a program stored in the ROM.

Further, the program may be recorded in a computer-readable recording medium and may be installed to the storage 62 of the control device 6 from this recording medium. The computer-readable recording medium may be, by way of non-limiting example, a hard disk (HD), a flexible disk (FD), a compact disk (CD), a magnet optical disk (MO), a memory card, or the like.

The storage 62 may be, by way of non-limiting example, a semiconductor memory device such as a RAM or a flash memory, or a storage device such as a hard disk or an optical disk.

[2. Flow of Substrate Processing]

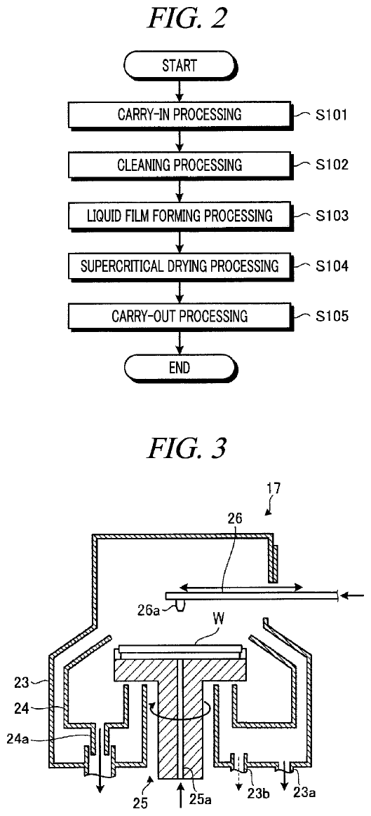

Now, a flow of a series of substrate processings performed in the above-described substrate processing system 1 will be explained with reference to FIG. 2 and FIG. 3. FIG. 2 is a flowchart illustrating a sequence of the series of substrate processings performed in the substrate processing system 1 according to the first exemplary embodiment. The series of substrate processings shown in FIG. 2 are performed under the control of the controller 61.

As shown in FIG. 2, in the substrate processing system 1, a carry-in processing is first performed (process S101). In the carry-in processing, the transfer device 13 (see FIG. 1) takes out the wafer W from the carrier C and places the taken wafer W on the delivery unit 14. Then, the transfer device 16 (see FIG. 1) takes out the wafer W from the delivery unit 14 and carries the taken wafer W into the liquid processing unit 17.

Subsequently, in the substrate processing system 1, the cleaning processing is performed in the liquid processing unit 17 (process S102). The liquid processing unit 17 removes a particle, a natural oxide film, or the like from the top surface of the wafer W by supplying various kinds of processing liquid onto the top surface of the wafer W as the pattern formation surface.

Then, in the substrate processing system 1, the liquid film forming processing is performed in the liquid processing unit 17 (process S103). The liquid processing unit 17 forms a liquid film of a IPA liquid on the top surface of the wafer W by supplying IPA in a liquid state (hereinafter, referred to as “IPA liquid”) onto the top surface of the wafer W after being subjected to the cleaning processing.

The wafer W after being subjected to the liquid film forming processing is transferred by the transfer device 16 into the delivery area 182 of the drying unit 18 disposed in the same processing block 5 and, then, transferred into the processing area 181 from the delivery area 182. Then, in the substrate processing system 1, the supercritical drying processing is performed in the processing area 181 (process S104). In the supercritical drying processing, the drying unit 18 dries the wafer W after being subjected to the liquid film forming processing by bringing the wafer W after being subjected to the liquid film forming processing into contact with the processing fluid in the supercritical state.

In the first exemplary embodiment, the drying unit 18 performs the supercritical drying processing on two sheets of wafers W at the same time. To elaborate, the transfer device 16 takes out the wafer W after being subjected to the liquid film forming processing from the liquid processing unit 17a between the two liquid processing units 17a and 17b disposed in the single processing block 5, for example, the processing block 5_1. Then, the transfer device 16 transfers the wafer W taken out of the liquid processing unit 17a into the delivery area 182a between the two delivery areas 182a and 182b belonging to the drying unit 18_1 disposed in the same processing block 5_1. Further, the transfer device 16 takes out the wafer W after being subjected to the liquid film forming processing from the other liquid processing unit 17b between the two liquid processing units 17a and 17b disposed in the processing block 5_1. Then, the transfer device 16 transfers the wafer W taken out of the liquid processing unit 17b into the delivery area 182b between the two delivery areas 182a and 182b belonging to the drying unit 18_1. Thereafter, the two sheets of wafers W are transferred into the processing area 181 from the individual delivery areas 182a and 182b to be subjected to the supercritical drying processing.

Further, the transfer device 16 may transfer the wafer W taken out of the liquid processing unit 17a disposed at the negative X-axis side into the delivery area 182b disposed at the positive X-axis side. Then, the transfer device 16 may transfer the wafer W taken out of the liquid processing unit 17b disposed at the positive X-axis side into the delivery area 182a disposed at the negative X-axis side. In the first exemplary embodiment, there is a difference in standby-time in the delivery areas 182a and 182b between the two sheets of wafers W. By setting a transfer distance of the first delivered wafer W to be shorter as stated above, such a stand-by time difference can be absorbed.

Subsequently, in the substrate processing system 1, a carry-out processing is performed (process S105). In the carry-out processing, the wafer W after being subjected to the supercritical drying processing is transferred from the processing area 181 into the delivery area 182. Thereafter, the transfer device 16 takes out the wafer W after being subjected to the supercritical drying processing from the delivery area 182 and transfer the taken wafer W into the delivery unit 14. Thereafter, the transfer device 13 takes out the wafer W after being subjected to the supercritical drying processing from the delivery unit 14 and transfers the taken wafer W into the carrier C.

[3. Configuration of Liquid Processing Unit]

Now, a configuration of the liquid processing unit 17 will be described with reference to FIG. 3. FIG. 3 is a diagram illustrating a configuration example of the liquid processing unit 17. The liquid processing unit 17 is configured as a single-wafer cleaning apparatus configured to clean the wafers W one by one by, for example, spin cleaning.

As depicted in FIG. 3, in the liquid processing unit 17, the wafer W is held substantially horizontally by a wafer holding mechanism 25 provided within an outer chamber 23 which forms a processing space therein. By rotating this wafer holding mechanism 25 around a vertical axis, the wafer W is rotated. Further, in the liquid processing unit 17, a nozzle arm 26 is advanced to a space above the wafer W being rotated, and by supplying a chemical liquid or a rinse liquid in a preset sequence from a chemical liquid nozzle 26a provided at a leading end of the nozzle arm 26, the cleaning processing on the top surface of the wafer W is performed.

Furthermore, in the liquid processing unit 17, a chemical liquid supply path 25a is formed within the wafer holding mechanism 25. A bottom surface of the wafer W is also cleaned by the chemical liquid or the rinse liquid supplied from this chemical liquid supply path 25a.

In the cleaning processing, a particle and an organic contaminant are first removed by, for example, SC1 solution (a mixed solution of ammonia and hydrogen peroxide) as an alkaline chemical liquid. Then, a rinse cleaning is performed by using deionized water (hereinafter, referred to as “DIW”) as the rinse liquid. Subsequently, a natural oxide film is removed by diluted hydrofluoric acid (hereinafter, referred to as “DHF”) as an acidic chemical liquid, and the rinse cleaning by the DIW is then performed.

The aforementioned various kinds of chemical liquids are received by the outer chamber 23 and an inner cup 24 disposed within the outer chamber 23, and then drained from a drain port 23a provided at a bottom of the outer chamber 23 and a drain port 24a provided at a bottom of the inner cup 24. Further, an atmosphere within the outer chamber 23 is exhausted through an exhaust port 23b provided at the bottom of the outer chamber 23.

The liquid film forming processing is performed after the rinsing processing in the cleaning processing. To elaborate, the liquid processing unit 17 supplies the IPA liquid onto the top surface and the bottom surface of the wafer W while rotating the wafer holding mechanism 25. Accordingly, the DIW remaining on both the top surface and the bottom surface of the wafer W is replaced with the IPA. Then, the liquid processing unit 17 stops the rotation of the wafer holding mechanism 25 gently.

The wafer W after being subjected to the liquid film forming processing is delivered, while having a liquid film of the IPA liquid formed on the top surface thereof, to the transfer device 16 by a non-illustrated delivery mechanism provided in the wafer holding mechanism 25, and, then, is taken out of the liquid processing unit 17. The liquid film formed on the wafer W suppresses the pattern collapse from occurring caused by evaporation (vaporization) of the liquid on the top surface of the wafer W during the transfer of the wafer W from the liquid processing unit 17 into the drying unit 18 and during the carry-in operation into the drying unit 18.

[4. Configuration of Drying Unit]

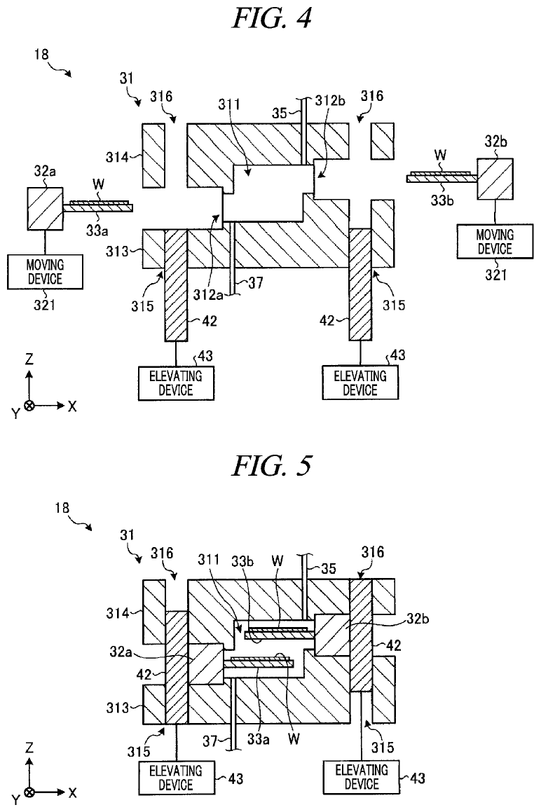

Now, a configuration of the drying unit 18 will be elaborated with reference to FIG. 4 and FIG. 5. FIG. 4 is a schematic cross sectional view illustrating the configuration of the drying unit 18 according to the first exemplary embodiment. Further, FIG. 5 is a schematic cross sectional view illustrating a state in which a plurality of wafers W is accommodated in a processing vessel.

As depicted in FIG. 4 and FIG. 5, the drying unit 18 is equipped with a processing vessel 31, a plurality of lids 32a and 32b and a plurality of holders 33a and 33b.

The processing vessel 31 is a pressure vessel capable of creating therein a high-pressure environment ranging from, e.g., 16 MPa to 20 MPa. The processing vessel 31 is disposed in the processing area 181 (see FIG. 1), and the supercritical drying processing is performed in a process space 311 within the processing vessel 31.

The processing vessel 31 has a rectangular shape when viewed from the top, and is provided with openings 312a and 312b at two side surfaces facing the delivery areas 182 in multiple (here, four) side surfaces thereof. In the first exemplary embodiment, the two delivery areas 182 are disposed at positions facing each other with the processing area 181 therebetween. Accordingly, the two openings 312a and 312b are provided at the two facing side surfaces in the multiple side surfaces of the processing vessel 31, here, at a side surface at a negative X-axis side and a side surface at a positive X-axis side. In this way, by providing the openings 312a and 312b at the different side surfaces of the processing vessel 31 respectively, an opening area per side surface can be reduced as compared to a case where the openings are provided at a single side surface. The smaller the opening area is, the smaller a pressure applied to a lock member 42 to be described later gets when the processing space 311 is set to be under a high pressure. Accordingly, pressure resistance of the processing vessel 31 can be easily obtained.

Each of the plurality of (here, two) lids 32a and 32b is connected to a moving device 321 and is horizontally moved between the processing area 181 and the delivery area 182 by the moving device 321. Accordingly, the lids 32a and 32b open or close the corresponding openings 312a and 312b of the processing vessel 31, respectively. To elaborate, the lid 32a (lower lid) disposed at the negative X-axis side opens or closes the opening 312a provided at the side surface of the processing vessel 31 at the negative X-axis side, and the lid 32b (upper lid) disposed at the positive X-axis side opens or closes the opening 312b provided at the side surface of the processing vessel 31 at the positive X-axis side.

Each of the plurality of (here, two) holders 33a and 33b is configured to hold a single sheet of the wafer W thereon horizontally. Each of the holders 33a and 33b is, for example, a frame body having a rectangular shape when viewed from the top, and is configured to hold the wafer W by supporting a peripheral portion of the wafer W from below.

In the two holders 33a and 33b, the holder 33a disposed at the negative X-axis side is provided at the lid 32a which is disposed at the negative X-axis side in the two lids 32a and 32b. Further, in the two holders 33a and 33b, the holder 33b disposed at the positive X-axis side is provided at the lid 32b which is disposed at the positive X-axis side in the two lids 32a and 32b.

These holders 33a and 33b are moved into the processing area 181 by the moving devices 321 along with the lids 32a and 32b and accommodated in the processing space 311. To elaborate, within the processing space 311, the holder 33a (lower holder) advanced into the processing space 311 from the negative X-axis side is placed under the holder 33b (upper holder) advanced into the processing space 311 from the positive X-axis side. In this way, since the two holders 33a and 33b are arranged within the processing vessel 31 with a distance therebetween in the vertical direction, a footprint increase of the processing vessel 31 can be suppressed, for example. Further, in the following description, when the lids 32a and 32b need not be distinguished from each other, they will sometimes be referred to as “lid 32.” Likewise, the holders 33a and 33b will sometimes be referred to as “holder 33”; and the openings 312a and 312b, as “opening 312.”

The processing vessel 31 is provided with a supply mechanism 35 and a drain mechanism 37. The supply mechanism 35 is connected to a supply device group of the supply unit 19 (see FIG. 1), and supplies the processing fluid supplied from the supply unit 19 into the processing space 311. The drain mechanism 37 drains the processing fluid from the processing space 311.

The supply mechanism 35 is provided at a ceiling surface of the processing space 311 within the processing vessel 31 and supplies the processing fluid from a supply opening opened downward into the processing space 311 in a vertically downward direction. The supply mechanism 35 is provided near, in the two openings 312 formed at the processing vessel 31, the opening 312 through which the upper holder 33 is carried (here, the opening 312 at the positive X-axis side). Further, the supply mechanism 35 may have a multiple number of supply openings arranged in the horizontal direction (Y-axis direction) orthogonal to the arrangement direction (X-axis direction) of the processing area 181 and the delivery area 182.

The drain mechanism 37 is provided at a bottom of the processing space 311 within the processing vessel 31 and drains the processing fluid from a drain opening opened upwards. The drain mechanism 37 is provided near, in the two openings 312 formed at the processing vessel 31, the opening 312 through which the lower holder 33 is carried (here, the opening 312 at the negative X-axis side). Further, the drain mechanism 37 may have a multiple number of drain openings arranged in the horizontal direction (Y-axis direction) orthogonal to the arrangement direction (X-axis direction) of the processing area 181 and the delivery area 182.

The drying unit 18 drains the processing fluid within the processing space 311 through the drain mechanism 37 while supplying the processing fluid into the processing space 311 from the supply mechanism 35. A damper configured to adjust a drain amount of the processing fluid from the processing space 311 is provided in a drain path for the processing fluid. The drain amount of the processing fluid is adjusted by the damper such that a pressure within the processing space 311 is adjusted to a required pressure. Accordingly, the supercritical state of the processing fluid is maintained in the processing space 311. In the following, the processing fluid in the supercritical state will sometimes be referred to as “supercritical fluid.”

The processing vessel 31 is equipped with a first protruding portion 313 and a second protruding portion 314 protruded outer than each corresponding opening 312 toward a lid opening direction of the opening 312. The first protruding portion 313 is protruded toward the X-axis direction from below a lower portion of the opening 312, and the second protruding portion 314 is protruded toward the X-direction from an upper portion of the opening 312.

The first protruding portion 313 is provided with first insertion through holes 315 extending from a top surface to a bottom surface of the first protruding portion 313. Further, the second protruding portion 314 is provided with second insertion through holes 316 at positions directly facing the first insertion through holes 315 in the vertical direction (that is, directly above the first insertion through holes 315). The second insertion through holes 316 extend from a top surface to a bottom surface of the second protruding portion 314.

Furthermore, the drying unit 18 is equipped with a plurality of (here, two) lock members 42. The lock members 42 are respectively inserted through the first insertion through holes 315 formed at the first protruding portion 313. Each lock member 42 is connected to an elevating device 43 configured to move the lock member 42 in the vertical direction.

[5. Operation Example of Drying Unit]

In the drying unit 18, a carry-in processing for two sheets of wafers W is first performed. In the carry-in processing, the drying unit 18 moves the lid 32a, which is disposed at the negative X-axis side, horizontally in the positive X-axis direction by the moving device 321, and moves the lid 32b, which is disposed at the positive X-axis side, horizontally in the negative X-axis direction by the moving device 321. Accordingly, the two sheets of wafers W held by the two holders 33a and 33b are accommodated in the processing space 311 of the processing vessel 31, and the processing space 311 is hermetically sealed by the two lids 32a and 32b. Here, a sequence and a timing for moving the two lids 32a and 32b are not particularly limited.

Further, the drying unit 18 moves the two lock members 42 upward by the elevating devices 43, thus allowing the lock members 42 to be respectively inserted into the second insertion through holes 316 formed at the second protruding portion 314.

Each lock member 42 presses the lid 32 toward the processing space 311 against the internal pressure generated by the processing fluid supplied into the processing space 311. Accordingly, the hermetically sealed state of the processing space 311 by the lids 32a and 32b can be maintained.

Then, a pressure raising processing is performed in the drying unit 18. In the pressure raising processing, the drying unit 18 supplies the processing fluid into the processing space 311 of the processing vessel 31 from the supply mechanism 35 to thereby increase the pressure of the processing space 311. Accordingly, the pressure of the processing space 311 is raised from an atmospheric pressure up to a processing pressure. The processing pressure is a pressure exceeding a threshold pressure (about 7.2 MPa) where the CO₂ as the processing fluid turns into the supercritical state. For example, the processing pressure may be about 16 MPa. Through this pressure raising processing, the processing fluid within the processing space is phase-changed into the supercritical state, and the IPA liquid accumulated on the surface of the wafer W is begun to be dissolved into the processing fluid in the supercritical state. Further, the processing fluid supplied from the supply unit 19 may be in the supercritical state or the liquid state.

Thereafter, a flow processing is performed in the drying unit 18. In the flow processing, the drying unit 18 drains, while maintaining the pressure of the processing space 311 at the processing pressure, the processing fluid supplied into the processing space to an outside of the processing space 311 through the drain mechanism 37, while supplying the processing fluid into the processing space 311 from the supply mechanism 35. Accordingly, a laminar flow of the processing fluid flowing in a preset direction around the wafers W is formed in the processing space 311.

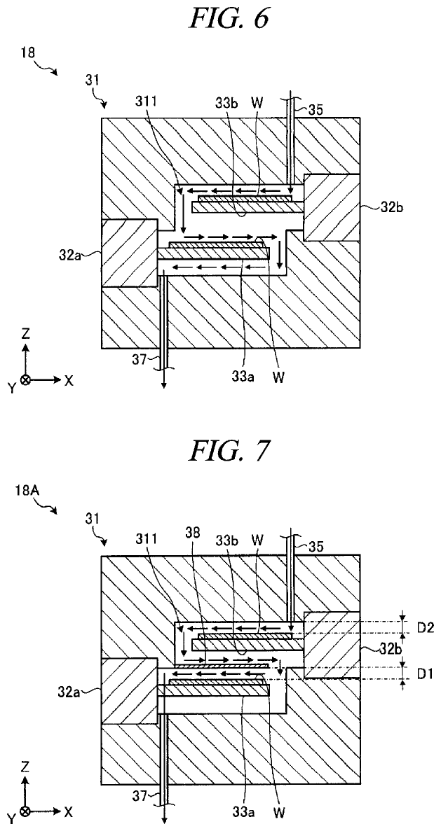

Here, a flow path for the processing fluid in the processing space 311 will be explained with reference to FIG. 6. FIG. 6 is a schematic cross sectional view illustrating an example of the flow path for the processing fluid in the processing space 311. In FIG. 6, illustration of a part of the components of the drying unit 18 is omitted.

As depicted in FIG. 6, after the processing fluid is supplied onto the top surface of the wafer W held by the upper lid 32b from the supply mechanism 35, the processing fluid flows in a space above the wafer W held by the upper holder 33b (i.e., upper wafer) along the top surface of the wafer W in the negative X-axis direction. Then, the processing fluid flows downwards in a space between a leading end of the upper holder 33b and an inner wall of the processing space 311, and then flows in a space above the wafer W held by the lower holder 33a along the top surface of the wafer W in the positive X-axis direction. Thereafter, the processing fluid flows downward in a space between a leading end of the lower holder 33a and an inner wall of the processing space 311, and then flows in a space between a bottom surface of the wafer W held by the lower holder 33a (i.e., lower wafer) and the bottom of the processing space 311 in the negative X-axis direction. Then, the processing fluid is drained to the outside of the processing space 311 from the drain mechanism 37.

The IPA liquid on the pattern formation surface (top surface) of the wafer W is gradually dissolved in the supercritical fluid as it comes into contact with the supercritical fluid in a high-pressure state (for example, 16 MPa), and then, is finally replaced by the supercritical fluid. Accordingly, a gap between patterns is filled with the supercritical fluid.

As stated above, according to the drying unit 18, since the flow of the processing fluid flowing along the top surface of each wafer W can be formed within the processing space 311, deterioration of the processing uniformity can be suppressed when performing the supercritical drying processing on the plurality of wafers W at the same time.

Thereafter, a decompression processing is performed in the drying unit 18. In the decompression processing, the drying unit 18 decompresses the processing space 311 from the high-pressure state to the atmospheric pressure. Accordingly, the supercritical fluid filled in the gap between the patterns is turned into the processing fluid in the normal state, i.e., the processing fluid in the gas state.

As stated above, in the drying unit 18, after replacing the IPA liquid existing on the pattern formation surface with the supercritical fluid, by returning the supercritical fluid into the processing fluid in the gas state, the IPA liquid is removed from the pattern formation surface, so that the pattern formation surface is dried.

The supercritical fluid has low viscosity as compared to a liquid (for example, the IPA liquid), and has high liquid-dissolving property. Besides, no interface exists between the supercritical fluid and a liquid or a gas which is in equilibrium with the supercritical fluid. Thus, by performing the supercritical drying processing, the liquid can be dried without being affected by the surface tension. That is, the pattern collapse can be suppressed in the drying processing.

Here, the IPA liquid is used as the dry-suppression liquid, and the CO₂ is used as the processing fluid. However, a liquid other than the IPA liquid may be used as the dry-suppression liquid, and a fluid other than the CO₂ may be used as the processing fluid.

As stated above, in the drying unit 18 according to the first exemplary embodiment, the supercritical drying processing is performed on the plurality of wafers W at the same time. Therefore, as compared to the conventional substrate processing apparatus which performs the supercritical drying processing on wafers W one by one, the efficiency of the supercritical drying processing can be improved. Further, as compared to a case where, for example, the number of drying units is increased to improve the efficiency of the supercritical drying processing, the cost increase of the substrate processing system 1 can be suppressed.

<Second Exemplary Embodiment>

FIG. 7 is a schematic cross sectional view illustrating a configuration of a drying unit according to a second exemplary embodiment. In the following various exemplary embodiments, illustration of a part of the drying unit may be omitted for the sake of easy understanding of the various exemplary embodiments.

As depicted in FIG. 7, a drying unit 18A according to the second exemplary embodiment is equipped with a partition plate 38. The partition plate 38 is a plate-shaped member disposed between the upper holder 33b and the lower holder 33a. In the processing vessel 31, the partition plate 38 extends from the inner wall of the processing space 311 at the negative X-axis side toward the inner wall at the positive X-axis side. A gap is provided between a leading end of the partition plate 38 and the inner wall of the processing space 311 at the positive X-axis side. Further, the partition plate 38 may be provided as a separate body from the processing vessel 31 or as a single body.

In the drying unit 18A according to the second exemplary embodiment, the processing fluid flows downwards in the space between the leading end of the upper holder 33b and the inner wall of the processing space 311, and then flows in a space between the partition plate 38 and the bottom surface of the upper wafer W in the positive X-axis direction. Then, the processing fluid flows in a space between a bottom surface of the partition plate 38 and the top surface of the lower wafer W in the negative X-axis direction, and is then drained to the outside of the processing space 311 from the drain mechanism 37 by being flown downwards after flowing through a hollow portion of the holder 33 having a frame-shape.

As stated above, by providing the partition plate 38 between the upper holder 33b and the lower holder 33a, the space above the lower holder 33a can be narrowed, and the processing fluid is allowed to come into contact with the lower wafer W more efficiently. Further, the partition plate 38 is disposed at a position where a distance D1 between the bottom surface of the partition plate 38 and the top surface of the lower wafer W becomes equal to a distance D2 between the ceiling surface of the processing space 311 and the top surface of the upper wafer W. Accordingly, the processing uniformity of the supercritical drying processing upon the wafers W can be improved.

Here, the second exemplary embodiment has been described for the case where the partition plate 38 is provided at the processing vessel 31. However, the partition plate 38 may be provided at the lower lid 32a or the lower holder 33a.

<Third Exemplary Embodiment>

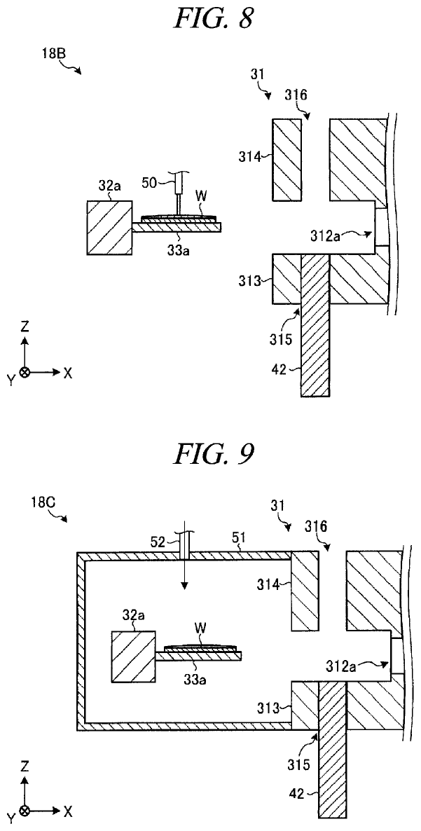

FIG. 8 is a schematic cross sectional view illustrating a configuration of a drying unit according to a third exemplary embodiment. As depicted in FIG. 8, a drying unit 18B according to the third exemplary embodiment is equipped with a supplement device 50. The supplement device 50 is disposed in, in the two delivery areas 182, the delivery area 182 (here, the delivery area 182a) which is a transfer destination of the wafer W delivered into the drying unit 18B for the first time, and replenishes the IPA onto the top surface of the wafer W held by the holder 33a in the delivery area 182a.

As stated above, the liquid film of the IPA liquid is formed on the top surface of the wafer W held by the holder 33a in the delivery area 182a. Since the transfer device 16 (see FIG. 1) transfers the wafers W one by one, the wafer W transferred into the drying unit 18B for the first time stands by in the delivery area 182a until a second sheet of the wafer W is transferred into the drying unit 18B. In the meantime, however, the IPA liquid on the top surface of the first transferred wafer W volatilizes, so there is a concern that there is caused a difference between liquid film thicknesses of the two wafers W.

As a resolution, in the drying unit 18B according to the third exemplary embodiment, the IPA liquid can be replenished, by using the supplement device 50, onto the wafer W having been transferred first into the drying unit 18B in the two wafers W processed at the same time. Therefore, according to the drying unit 18B of the third exemplary embodiment, the difference in the liquid film thickness between the two sheets of wafers W can be suppressed.

Further, the drying unit 18B may be equipped with the supplement device 50 in each of the two delivery areas 182 (for example, the delivery area 182a and the delivery area 182b).

<Fourth Exemplary Embodiment>

FIG. 9 is a schematic cross sectional view illustrating a configuration of a drying unit according to a fourth exemplary embodiment. As depicted in FIG. 9, a drying unit 18C according to the fourth exemplary embodiment is equipped with a box body 51 surrounding, in the two delivery areas 182, the delivery area 182 (here, the delivery area 182a) which is a transfer destination of the wafer W transferred into the drying unit 18C for the first time. The box body 51 is configured to accommodate therein the lid 32a, the holder 33a and the wafer W disposed in the delivery area 182a. Further, the drying unit 18C according to the fourth exemplary embodiment is equipped with an atmosphere supply 52 configured to supply an IPA atmosphere into the box body 51.

According to the drying unit 18C of the fourth exemplary embodiment, since the IPA atmosphere is supplied into the box body 51 by using the atmosphere supply 52, the volatilization of the liquid film of the IPA liquid on the top surface of the wafer W can be suppressed. Accordingly, the difference in the liquid film thickness between the two sheets of wafers W can be suppressed.

Moreover, the drying unit 18C may be equipped with the box body 51 and the atmosphere supply 52 in each of the two delivery areas 182 (for example, the delivery area 182a and the delivery area 182b).

<Fifth Exemplary Embodiment>

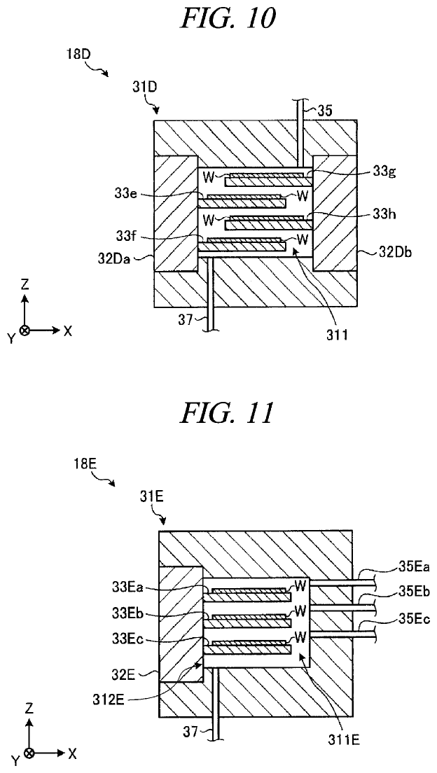

FIG. 10 is a schematic cross sectional view illustrating a configuration of a drying unit according to a fifth exemplary embodiment. As depicted in FIG. 10, a drying unit 18D according to the fifth exemplary embodiment includes a processing vessel 31D, two lids 32Da and 32Db, and four holders 33e to 33h.

Each of the lids 32Da and 32Db is configured to support two of the four holders 33e to 33h. To elaborate, the lid 32Da supports the holders 33e and 33f, and the lid 32Db supports the holders 33g and 33h.

In the processing space 311, the four holders 33e to 33h are arranged such that the holders 33e and 33f supported by the lid 32Da disposed at the negative X-axis side and the holders 33g and 33h supported by the lid 32Db disposed at the positive X-axis side are alternately provided.

As stated above, the drying unit 18D may be equipped with three or more holders 33e to 33h. In this case, by arranging the holders 33e and 33f supported by the one lid 32Da and the holders 33g and 33h supported by the other lid 32Db alternately, a distance between the multiple holders 33e to 33h supported by the single lid 32Da (32Db) can be increased. Accordingly, the delivery of the wafers W by the transfer device 16 is easily performed. Further, by arranging the holders 33e and 33f supported by the one lid 32Da and the holders 33g and 33h supported by the other lid 32Db alternately, the flow of the processing fluid flowing along the top surfaces of the wafers W in sequence starting from the uppermost wafer W can be formed within the processing space 311.

In the fifth exemplary embodiment, each processing block 5 may be equipped with four liquid processing units 17.

Here, the number of the holders provided at the one lid 32Da and the number of the holders provided at the other lid 32Db are same. However, the number of the holders provided at the one lid 32Da and the number of the holders provided at the other lid 32Db may be different.

<Sixth Exemplary Embodiment>

FIG. 11 is a schematic cross sectional view illustrating a configuration of a drying unit according to a sixth exemplary embodiment. As depicted in FIG. 11, a drying unit 18E according to the sixth exemplary embodiment is equipped with a processing vessel 31E having a single opening 312E, a single lid 32E, and a plurality of holders 33Ea to 33Ec. The plurality of (here, three) holders 33Ea to 33Ec are provided at the single lid 32E.

Further, the drying unit 18E is further equipped with a plurality of (here, three) supply mechanisms 35Ea to 35Ec. These supply mechanisms 35Ea to 35Ec are provided in a side surface of the processing vessel 31E facing a side surface where the opening 312E of the processing vessel 31E is provided.

The supply mechanisms 35Ea to 35Ec correspond to a plurality of wafers W held by the plurality of holders 33Ea to 33Ec, respectively. To be specific, the upper supply mechanism 35Ea among the three supply mechanisms 35Ea to 35Ec is disposed at a height position between the top surface of the wafer W held by the upper holder 33Ea among the three holders 33Ea to 33Ec and the ceiling surface of the processing space 311E. Likewise, the intermediate supply mechanism 35Eb is disposed at a height position between the top surface of the wafer W held by the intermediate holder 33Eb and the bottom surface of the upper wafer W, and the lower supply mechanism 35Ec is disposed at a height position between the top surface of the wafer W held by the lower holder 33Ec and the bottom surface of the intermediate wafer W.

Each of the supply mechanisms 35Ea to 35Ec supplies the processing fluid along the top surface of the corresponding wafer W. Accordingly, in the drying unit 18E according to the sixth exemplary embodiment, the processing fluid can be uniformly supplied to the plurality of wafers W.

Further, the drying unit 18E according to the sixth exemplary embodiment has a configuration in which the plurality of holders 33Ea to 33Ec are provided at the single lid 32E. With this configuration, only one delivery area 182 is provided, so that the footprint increase can be suppressed.

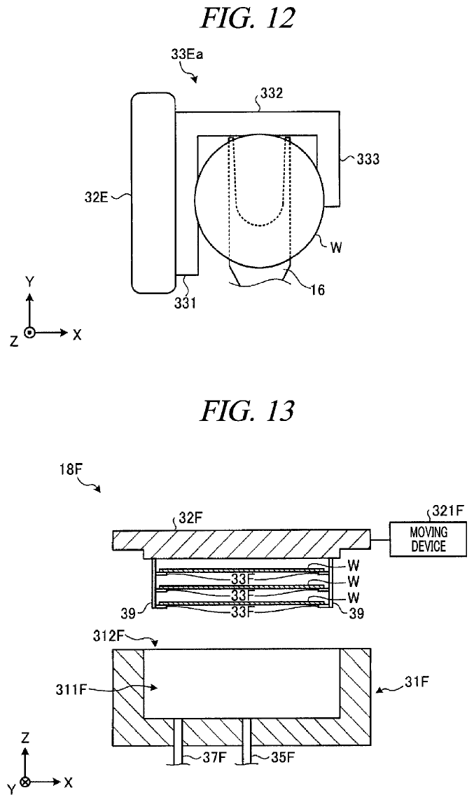

FIG. 12 is a schematic plan view illustrating a configuration of the holder 33Ea according to the sixth exemplary embodiment. Since the holders 33Eb and 33Ec have the same configuration as that of the holder 33Ea, description of the holders 33Eb and 33Ec will be omitted here.

As depicted in FIG. 12, when viewed from the top, the holder 33Ea has a hook shape, and a portion of the holder 33Ea which interferes with the transfer device 16 in the delivery of the wafer W is notched. To be specific, the holder 33Ea has a first supporting portion 331, a second supporting portion 332 and a third supporting portion 333. The first supporting portion 331 extends in the Y-axis direction and supports the peripheral portion of the wafer W at the negative X-axis side. The second supporting portion 332 extends in the X-axis direction from an end of the first supporting portion 331 at the positive Y-axis side, and supports the peripheral portion of the wafer W at the positive Y-axis side. The third supporting portion 333 extends in the Y-axis direction from an end of the second supporting portion 332 at the positive X-axis side, and supports the peripheral portion of the wafer W at the positive X-axis side. The holder 33Ea supports the wafer W at three points with the first supporting portion 331, the second supporting portion 332 and the third supporting portions 333.

If the plurality of holders 33Ea to 33Ec are provided at the single lid 32E, a distance between the holders 33Ea to 33Ec is shortened, and it may be difficult to accomplish the delivery of wafers W by the transfer device 16. As a resolution, since the holder 33E has the above-described shape, the interference between the transfer device 16 and the holders 33Ea to 33Ec can be suppressed even if the distance between the plurality of holders 33Ea to 33Ec is small.

<Seventh Exemplary Embodiment>FIG. 13 is a schematic cross sectional view illustrating a configuration of a drying unit according to a seventh exemplary embodiment. As shown in FIG. 13, a drying unit 18F according to the seventh exemplary embodiment includes a processing vessel 31F, a lid 32F and a plurality of holders 33F.

The processing vessel 31F has an opening 312F at a top thereof. The lid 32F is disposed above the processing vessel 31F, and is moved in the vertical direction by a moving device 321F.

The holders 33F are provided at a bottom surface of the lid 32F, which is configured as a ceiling surface of a processing space 311F, with vertically extending supporting members 39 therebetween. The holders 33F are arranged at a regular distance therebetween in the vertical direction.

The drying unit 18F moves the lid 32F downwards by using the moving device 321F. Accordingly, the holders 33F provided at the lid 32F are accommodated in the processing space 311F of the processing vessel 31F, and the processing space 311F is hermetically sealed by the lid 32F.

The processing vessel 31F is provided with a supply mechanism 35F, and the processing fluid is supplied into the processing space 311F through the supply mechanism 35F. Further, the processing vessel 31F is provided with a drain mechanism 37F, and the processing fluid is drained from the processing space 311F through the drain mechanism 37F. In this example, the supply mechanism 35F and the drain mechanism 37F are provided at a bottom surface of the processing space 311F. However, the supply mechanism 35F and the drain mechanism 37F may be provided at a side surface of the processing space 311F. In such a case, the drying unit 18F needs to have a plurality of supply mechanisms configured to supply the processing fluid along the top surfaces of the wafers W. Specifically, it is desirable that the number of the supply mechanisms is the same as the number of the wafers W. Further, this configuration in which the plurality of supply mechanisms configured to supply the processing fluid along the top surfaces of the corresponding wafers W held by the plurality of holders is provided may also be applicable to the drying units according to the other exemplary embodiments.

As described above, the holders 33F may be provided at the lid 32F configured to open or close the processing space 31F having an open top.

<Other Exemplary Embodiments>

In the first to fourth exemplary embodiments, the opening 312 is provided at each of the two facing side surfaces of the processing vessel 31 among the multiple side surfaces of the processing vessel 31, and one wafer W is carried in through the one opening 312 and the other wafer W is carried in through the other opening 312 at the opposite side thereof. However, without being limited thereto, the two openings 312 may be respectively provided at the side surfaces orthogonal to each other among the multiple side surfaces of the processing vessel 31. By way of example, the openings 312 may be respectively provided at the side surface at the negative X-axis side and at the side surface at the negative Y-axis side among the multiple side surfaces of the processing vessel 31. This configuration may also be applied to the lid 32D of the fifth exemplary embodiment.

Further, the number of the liquid processing units 17 disposed in each processing block 5 need not necessarily be the same as the number of the wafers W processed in the drying unit 18 (18A to 18F) at the same time. For example, in the substrate processing system 1 according to the first exemplary embodiment, the number of the liquid processing units 17 disposed in the processing block 5 may be one.

As stated so far, a substrate processing apparatus (as an example, the drying unit 18 (18A to 18F)) according to the exemplary embodiments is a substrate processing apparatus configured to perform a drying processing of drying the substrate (as an example, the wafer W) by using the processing fluid in the supercritical state. The substrate processing apparatus according to the exemplary embodiments is equipped with a processing vessel (as an example, the processing vessel 31 (31D to 31F)) and a plurality of holders (as an example, the holders 33 (33E, 33F)). The processing vessel is a vessel in which the drying processing is performed. The plurality of holders support different substrates respectively within the processing vessel. Thus, according to the substrate processing apparatus of the exemplary embodiments, the efficiency of the supercritical drying processing can be improved.

The plurality of holders (as an example, the holders 33 (33E, 33F)) may be arranged at a regular distance therebetween in the vertical direction within the processing vessel. With this configuration, the footprint increase of the processing vessel can be suppressed.

The substrate processing apparatus according to the exemplary embodiments (as an example, the drying unit 18 (18A to 18D)) may be equipped with a first lid (as an example, the lid 32 (32D) disposed at the negative X-axis side) and a second lid (as an example, the lid 32 (32D) disposed at the positive X-axis side). The first lid is capable of opening or closing a first opening (as an example, the opening 312 at the negative X-axis side) provided at a first side surface (as an example, the side surface at the negative X-axis side) of the processing vessel (as an example, the processing vessel 31 (31D)). The second lid is capable of opening or closing a second opening (as an example, the opening 312 at the positive X-axis side) provided at a second side surface (as an example, the side surface at the positive X-axis side) of the processing vessel. In this case, a part of the plurality of holders (as an example, one or more holders 33 disposed at the negative X-axis side) may be provided at the first lid. Further, a remaining part of the plurality of holders (as an example, one or more holders 33 disposed at the positive X-axis side) may be provided at the second lid. As stated above, by providing the plurality of openings at the different side surfaces of the processing vessel respectively, the pressure resistance of the processing vessel can be easily obtained.

Regarding the arrangement of the plurality of holders (as an example, the plurality of holders 33 belonging to the drying unit 18D), a part of the plurality of holders (as an example, a multiplicity of holders 33 disposed at the negative X-axis side) and a remaining part of the plurality of holders (as an example, a multiplicity of holders 33 disposed at the positive X-axis side) may be arranged alternately in the processing vessel (as an example, the processing vessel 31D). With this configuration, the distance between the plurality of holders supported by the single lid can be increased, so that the delivery of substrates by the transfer device can be eased.

The second side surface (as an example, the side surface at the positive X-axis side) may be located at a position facing the first side surface (as an example, the side surface at the negative X-axis side) among the multiple side surfaces belonging to the processing vessel (as an example, the processing vessel 31 (31D)). Accordingly, by arranging the first side surface and the second side surface in the lengthwise direction of the substrate processing system 1, the increase of the width of the substrate processing system 1 in the widthwise direction can be suppressed.

The substrate processing apparatus according to the exemplary embodiment (as an example, the drying unit 18E) may be further equipped with a lid (as an example, the lid 32E) configured to open or close an opening (as an example, the opening 312E) provided at a side surface of the processing vessel (as an example, the processing vessel 31E). In this case, the plurality of holders (as an example, the holders 33E) may be provided at the lid (as an example, the lid 32E). Accordingly, as only one delivery area 182 is provided, the footprint increase can be suppressed.

The substrate processing apparatus according to the exemplary embodiments (as an example, the drying unit 18F) may be further equipped with a lid (as an example, the lid 32F) capable of opening or closing the processing vessel (as an example, the processing vessel 31F) having the open top. In this case, the plurality of holders (as an example, the holders 33F) may be provided at the lid (as an example, the lid 32F). Accordingly, the footprint increase can be suppressed.

The substrate processing apparatus according to the exemplary embodiments (as an example, the drying unit 18 (18A to 18D)) may be equipped with the supply mechanism 35 and the drain mechanism 37. Within the processing vessel (as an example, the processing vessel 31 (31D)), the supply mechanism 35 is disposed above a substrate held by the uppermost holder among the plurality holders (as an example, the holders 33), and supplies the processing fluid into the processing vessel. Within the processing vessel, the drain mechanism 37 is disposed below a substrate held by the lowermost holder among the plurality of holders, and drains the processing fluid from the inside of the processing vessel. Accordingly, the flow of the processing fluid flowing along the top surfaces of the substrates in sequence starting from the uppermost substrate can be formed within the processing space.

The substrate processing apparatus according to the exemplary embodiments (as an example, the drying unit 18A) may be further equipped with, within the processing vessel (as an example, the processing vessel 31), the partition plate 38 disposed between the two neighboring holders adjacent to each other in the vertical direction. With this configuration, the space above the lower holder between the two holders adjacent to each other in the vertical direction can be narrowed, so that the processing fluid can come into contact with the substrate held by the lower holder more efficiently.

The substrate processing apparatus according to the exemplary embodiments (as an example, the drying unit 18A), the upper holder 33b among the two holders 33a and 33b adjacent in the vertical direction may be the uppermost holder among the plurality of holders 33a and 33b. In this case, the partition plate 38 may be placed at a position where the distance D1 between the top surface of the substrate held by the lower holder 33a among the two holders 33a and 33b adjacent in the vertical direction and the bottom surface of the partition plate 38 becomes equal to the distance D2 between the top surface of the substrate held by the upper holder 33b among the two holders 33a and 33b adjacent in the vertical direction and the ceiling surface of the processing vessel 31. With this configuration, the processing uniformity of the supercritical drying processing upon the plurality of substrates can be improved.

The substrate processing apparatus according to the exemplary embodiments (as an example, the drying unit 18E) may be further equipped with a plurality of supply mechanisms (as an example, the supply mechanism 35E) configured to supply the processing fluid along a top surface of a corresponding substrate among a plurality of substrates held by the plurality of holders (as an example, the holders 33E) within the processing vessel (as an example, the processing space 311E). Accordingly, the processing fluid can be uniformly supplied to the plurality of substrates accommodated in the processing vessel.

The substrate processing apparatus according to the exemplary embodiments (as an example, the drying unit 18B) may be further equipped with the supplement device 50 disposed in the delivery area adjacent to the processing vessel (as an example, the delivery area 182) and configured to replenish a liquid (as an example, IPA) onto a top surface of a substrate on which a liquid film of the liquid is formed. Accordingly, the generation of the difference in the liquid film thickness between the plurality of substrates can be suppressed.

The substrate processing apparatus according to the exemplary embodiments (as an example, the drying unit 18C) may be further equipped with the box body 51 and the atmosphere supply 52. The box body 51 is a box body surrounding the delivery area adjacent to the processing vessel (as an example, the delivery area 182), and is capable of accommodating a substrate on a top surface of which a film of a liquid (as an example, IPA) is formed. The atmosphere supply 52 supplies an atmosphere of the liquid into the box body 51. Accordingly, the generation of the difference in the liquid film thickness between the plurality of substrates can be suppressed.

According to the present disclosure, it is possible to improve the efficiency of the supercritical drying processing.

The exemplary embodiments stated above are not intended to be anyway limiting. The above-described exemplary embodiments may be omitted, replaced and modified in various ways without departing from the scope and the spirit of claims.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus configured to perform a drying processing of drying substrates by using a processing fluid in a supercritical state, the substrate processing apparatus comprising:
a processing vessel in which the drying processing is performed; and
multiple holders configured to respectively hold the substrates within the processing vessel.

2. The substrate processing apparatus of claim 1,
wherein the multiple holders are arranged at a distance therebetween in a vertical direction within the processing vessel.

3. The substrate processing apparatus of claim 2, further comprising:
a first lid configured to open or close a first opening provided at a first side surface of the processing vessel; and
a second lid configured to open or close a second opening provided at a second side surface of the processing vessel,
wherein a part of the multiple holders are provided at the first lid, and
a remaining part of the multiple holders are provided at the second lid.

4. The substrate processing apparatus of claim 3,
wherein the multiple holders are arranged such that the part of the multiple holders and the remaining part of the multiple holders are alternately disposed within the processing vessel.

5. The substrate processing apparatus of claim 3,
wherein the second side surface is located at a position directly facing the first side surface in multiple side surfaces of the processing vessel.

6. The substrate processing apparatus of claim 2, further comprising:
a lid configured to open or close an opening provided at a side surface of the processing vessel,
wherein the multiple holders are provided at the lid.

7. The substrate processing apparatus of claim 2, further comprising:
a lid configured to open or close the processing vessel having an open top,
wherein the multiple holders are provided at the lid.

8. The substrate processing apparatus of claim 2, further comprising:
a supply mechanism provided above the substrate held by an uppermost holder in the multiple holders within the processing vessel, and configured to supply the processing fluid into the processing vessel; and
a drain mechanism provided under the substrate held by a lowermost holder in the multiple holders within the processing vessel, and configured to drain the processing fluid from an inside of the processing vessel.

9. The substrate processing apparatus of claim 8, further comprising:
a partition plate disposed between two holders adjacent to each other in the vertical direction within the processing vessel.

10. The substrate processing apparatus of claim 9,
wherein an upper holder between the two holders adjacent to each other in the vertical direction is the uppermost holder in the multiple holders, and
the partition plate is disposed at a position where a distance between a top surface of the substrate held by a lower holder between the two holders adjacent to each other in the vertical direction and a bottom surface of the partition plate becomes equal to a distance between a top surface of the substrate held by the upper holder between the two holders adjacent to each other in the vertical direction and a ceiling surface of the processing vessel.

11. The substrate processing apparatus of claim 1, further comprising:
multiple supply mechanisms each configured to supply, within the processing vessel, the processing fluid along a top surface of a corresponding substrate in the substrates held by the multiple holders.

12. The substrate processing apparatus of claim 1, further comprising:
a supplement device disposed in a delivery area adjacent to the processing vessel, and configured to supplement a liquid onto a top surface of the substrate having a film of the liquid formed thereon.

13. The substrate processing apparatus of claim 1, further comprising:
a box body, surrounding a delivery area adjacent to the processing vessel, configured to accommodate therein the substrate having a film of a liquid formed thereon; and
an atmosphere supply configured to supply an atmosphere of the liquid into the box body.

14. A substrate processing method, comprising:
holding substrates by using multiple holders belonging to a substrate processing apparatus;
accommodating the multiple holders holding the substrates in a processing vessel of the substrate processing apparatus; and
drying the substrates by using a processing fluid in a supercritical state within the processing vessel.
